(19) United States
(12) Patent Application Publication
(10) Pub. No.: US 2026/0173883 A1
(43) Pub. Date: Jun. 18, 2026

(54) LASER DAMAGE MITIGATION STRUCTURE AND METHOD

(71) Applicant: International Business Machines Corporation, Armonk, NY (US)

(72) Inventors: Qianwen Chen, Fort Collins, CO (US); Joshua Mark Rubin, Albany, NY (US); Neng Liu, Albany, NY (US); Hsianghan Hsu, Latham, NY (US); Tao Li, Slingerlands, NY (US); Ruilong Xie, Niskayuna, NY (US)

(21) Appl. No.: 18/979,835

(22) Filed: Dec. 13, 2024

(51) Int. Cl. H01L 23/552; G02B 5/28

(52) U.S. Cl. CPC H10W 42/20; G02B 5/281

(57) ABSTRACT

A laser damage mitigation structure for semiconductor devices comprising a top surface of a multilayer-stack of alternating high-index refractive dielectric material and low-index dielectric material layers adjacent to a top BEOL layer to serve as reflector for incoming laser beam. In embodiments, the geometrical thickness t_{H} of the high-index refractive dielectric material layer(s) is t_{H}=nλ/(4n_{H}) and the geometrical thickness t_{L} of the low-index refractive dielectric material layer(s) is t_{L}=nλ/(4n_{L}), respectively, where n_{H} is an index of refraction of the high-index dielectric material and n_{L} is an index of refraction of the low-index dielectric material and λ is the wavelength of the incident laser beam used to de-bond the device wafer from the handle (or carrier) wafer.

### BACKGROUND

The present disclosure relates in general to wafer debonding process, and more particularly to a system and method for laser-assisted wafer debonding that avoids and mitigates potential damage to circuit structures.

In the field of semiconductor wafer processing, increasing demands for large-scale integration, high density silicon packages have resulted in making semiconductor dies very thin. The handling of thinned Si wafers presents a significant challenge to most automated semiconductor processing equipment.

For example, as shown in FIG. 1, in order to facilitate the processing of a thinned device wafer 10 having electronic devices 12 and top level conductive interconnect structures 18, a mechanical handler wafer (or carrier wafer) 15 is typically attached to the device wafer to enhance the mechanical integrity of the device wafer during processing. When processing of the device wafer is complete, the handler wafer 15 needs to be released from the device wafer 10.

One common approach to handling a thinned device wafer 10 is to laminate the handler wafer 15 with the device wafer 10 using a bonding structure that bonds the device wafer and the handler wafer together. The bonding structure can include a release layer 20 formed of a conductive material and/or specially developed polymeric adhesives 22. Depending on factors such as the processing steps, the product requirements, and the type of the adhesive, various techniques have been used or proposed to debond or separate a thinned device wafer 10 from a mechanical handler wafer 15, including thermal release, chemical dissolving, mechanical release, and laser ablation techniques. For example, a laser ablation process is performed to ablate the polymeric adhesive and achieve debonding between a glass mechanical handler wafer and the device wafer.

Further, the bonding structure can be irradiated with infrared (IR) energy through the handler wafer 15 to substantially or completely vaporize the release layer 20 such that the device wafer is released from the handler wafer as a direct result of the substantial or complete vaporization of the release layer.

Nonetheless, there remains the concern of a possibility of damage 30 occurring on the electronic devices 12 by the transmittance of laser energy 35.

### SUMMARY

In one aspect, there is provided a laser damage mitigation structure for a semiconductor wafer and method for infrared (IR) laser debonding that is configured to avoid damages on sensitive circuits formed in the semiconductor wafer.

In this aspect, there is provided a laser damage mitigation structure for a semiconductor wafer that is subject to a laser-assisted wafer debonding used during a semiconductor device manufacturing process.

In one aspect, the laser damage mitigation structure includes a stack of alternating layers of dielectric material, the alternating dielectric material layers comprising one or more successive pairs of layers of a high-refractive index dielectric material layer and a low-refractive index dielectric material layer of targeted thicknesses configured to reflect an incident laser beam.

In this aspect, a thickness t_{H} of the high-refractive index dielectric material layer is t_{H}=nλ/(4n_{H}), where n_{H} is an index of refraction of the high-index dielectric material and λ is the wavelength of the incident laser beam, and a thickness t_{L} of the low-refractive index dielectric material layer is t_{L}=nλ/(4n_{L}), where n_{L} is an index of refraction of the low-index dielectric material and λ is the wavelength of the incident laser beam

In an embodiment, there is provided a handle wafer bonded to a top surface of the stack, the handle wafer being bonded to a top surface of the stack using one or more of: a bonding material of conductive material forming a laser release layer, a polymeric adhesive material layer, or both a laser release layer and adhesive layer.

In an embodiment, there is provided a semiconductor structure. The semiconductor structure comprises: a stack of alternating layers of dielectric material, the alternating dielectric material layers comprising successive pairs of a high-refractive index dielectric material layer and a low-refractive index dielectric material layer and the stack having a side edge abutting a side edge of a back-end-of-line metal layer structure, the stack of alternating layers configured to reflect an incident laser beam.

In a further aspect, there is provided a method of forming laser damage mitigation structure on a semiconductor wafer. The method comprises: depositing a low-refractive index dielectric material layer of a target thickness on a top surface of the semiconductor die, having devices formed therein; depositing a high-refractive index dielectric material layer of a target thickness on top the deposited low-refractive index dielectric material layer, the deposited low-refractive index dielectric material layer and high-refractive index dielectric material layer defining an initial pair of layers; and repeating the depositing of alternating layers of low-refractive index dielectric material layer and high-refractive index dielectric material layer on the initial pair to form a stacked structure of alternating low-refractive index and high-refractive index layers on top of the device wafer.

In a further embodiment, there is provided a damage mitigation structure for a semiconductor wafer. The damage mitigation structure comprises: a stack of alternating layers of dielectric material, the alternating dielectric material layers comprising successive pairs of a high-refractive index dielectric material layer and a low-refractive index dielectric material layer and the stack having a side edge abutting side edges of at least one back-end-of-line metal layer structure; and the stack of alternating layers configured to reflect an incident laser beam.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 depicts the conventional processing of a thinned device wafer having electronic devices and including a mechanical handler wafer attached to the device wafer to enhance the mechanical integrity of the device wafer during processing;

FIG. 2A depicts a laser damage mitigation semiconductor wafer die structure according to an embodiment of the present disclosure;

FIG. 2B depicts a configuration of the laser damage mitigation structure having a sidewall edge abutting and touching different side edge portion of a BEOL metal bonding layer structure (upper, middle, or bottom, etc) and/or of a BEOL via contact structure;

FIG. 2C depicts a configuration of the laser damage mitigation structure having a sidewall edge abutting and touching the via contact or portion of a via contact below a metal bonding structure;

FIG. 3 depicts a close-up view of a portion of the laser damage mitigation structure shown in FIG. 2A;

FIG. 4 depicts a plot illustrating a degree of reflectance (ordinate axis) of the laser damage mitigation structure as a function of incident light wavelength (abscissa) according to an embodiment; and

FIGS. 5A-5F depict a process flow for fabricating the laser damage mitigation structure atop a semiconductor wafer according to embodiments of the disclosure.

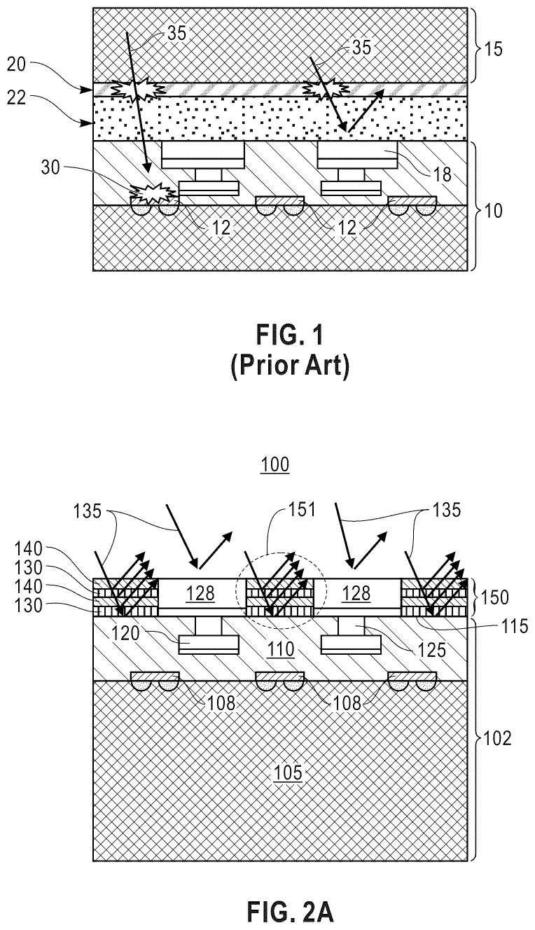

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. In addition, features described herein can be used in combination with other described features in each of the various possible combinations and permutations. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

Unless otherwise specifically defined herein, all terms are to be given their broadest possible interpretation including meanings implied from the specification as well as meanings understood by those skilled in the art and/or as defined in dictionaries, treatises, etc. It should also be noted that, as used in the specification and the appended claims, the singular forms “a”, “an” and “the” include plural referents unless otherwise specified, and that the terms “includes”, “comprises”, and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element as a layer, region or substrate is referred to as

being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath”, “directly under”, or “in contact with” another element, there are no intervening elements present.

Embodiments herein provide an infrared (IR) laser debonder to use for a Si wafer as a carrier, e.g., for chiplet technology. Benefits of using an Si carrier wafer are: tool compatibility, less contamination, thermal CTE match and high heat dissipate, as well as its ability to simplify supply chain.

An embodiment provides a laser damage mitigation structure and method for IR laser debonding.

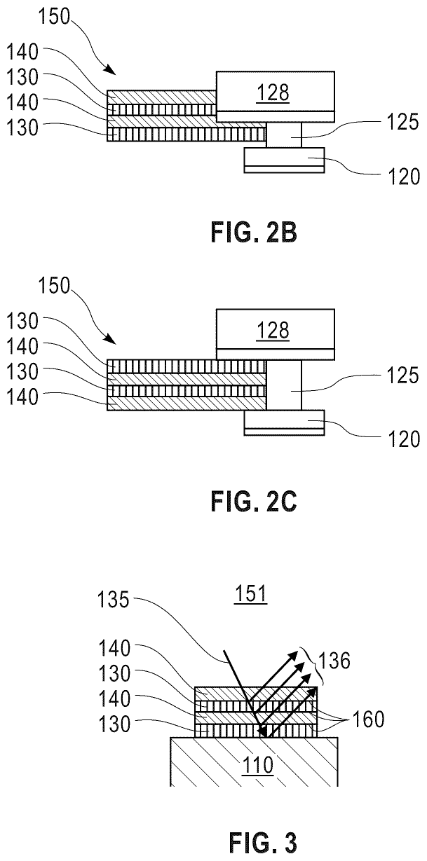

Referring to FIG. 2A, there is provided a laser damage mitigation semiconductor wafer die structure 100 according to an embodiment of the present disclosure.

As shown in FIG. 2A, a device wafer or chip/chiplet wafer die 102 includes a thinned substrate or device layer 105 upon which are formed front-end-of-line (FEOL) devices 108, e.g., device components such as transistors, capacitors, resisters forming semiconductor circuits and systems. Upon thinned layer 105 is an interlevel dielectric (IDL) material layer 110 within which are formed conductive, e.g., metal, structures and layers formed as part of back-end-of-line (BEOL) semiconductor manufacturing processes. These structures can include but are not limited to connector/interconnect structures 120, e.g., contacts, metallization wiring, via contacts 125, top metal layer pads or metal bonding structures 128 for chip to package connections, etc. formed in the ILD layer 110. The device wafer structure can function as a carrier for chiplet technology, e.g., with the devices 108 forming heterogeneous components or specialized dies having different functionalities. Whether die 102 is a chiplet or a wafer, it is the case that laser debonding can occur at a wafer level. However, sometimes the wafer is diced with the carrier and the debonding happens at the chip/chiplet level. The latter might be necessary if the carrier needs to perform an assembly step on another wafer or package prior to getting rid of the carrier.

In an embodiment, formed on a top surface 115 of the ILD layer 110 is a laser damage mitigation structure 150 including a stack of alternating layers of different dielectric materials. For example, laser damage mitigation structure 150 includes a multilayer-stack of alternate high-refractive index dielectric material and low-refractive index dielectric material layers 130, 140 stacked on surface 115 of a top BEOL layer that serve as a reflector for incoming laser beam, e.g., IR laser. Although the multi-layer stack of laser damage mitigation structure 150 is depicted directly on top surface 115 and having sidewall edges wholly abutting the sidewall edges of metal bonding structures 128, this configuration is not so limited. For example, as shown in FIG. 2B, the laser damage mitigation structure 150 can have side edges formed to coincide (abut, touch or contact) with at least a sidewall portion of one or more back-end-of-line metal layer structure (at and between different metallization layers), e.g., at least a sidewall portion of both BEOL metal bonding structure 128 and underlying via contact structure 125. Further, the laser damage mitigation structure 150 can have a side edge formed to coincide (i.e., abut and contact) with only a portion of a side edge of a metal bonding structure 128 (upper, middle, or bottom portion, etc). As shown in FIG. 2C, the laser damage mitigation structure 150 can have side edges formed to coincide (abut and contact) with the via contact 125 or portion of a via contact 125, e.g., below the metal bonding structure 128. In an embodiment, use of a high refractive index material, such as Si₃N₄, has higher dielectric constant, which could create more capacitive coupling between BEOL features, might require a balance between how the multi-layer stack is used vs. the electrical performance of the BEOL layers. Additionally, depending on metal layer thicknesses, the multi-layer stack of laser damage mitigation structure 150 could require more alternating high-refractive index dielectric material and low-refractive index dielectric material layers 130, 140 than that which can coincide (abut and contact) with a single metal layer bonding structure 128 to achieve sufficient reflectance.

In an embodiment of the laser damage mitigation multi-layer stack structure 150, the geometrical thickness t_{H} of the high-refractive index dielectric material layer(s) 130 is t_{H}=nλ/(4n_{H}) and the geometrical thickness t_{L} of the low-refractive index dielectric material layer(s) 140 is t_{L}=nλ/(4n_{L}), respectively, where n_{H} is an index of refraction of the high-index dielectric material and n_{L} is an index of refraction of the low-index dielectric material and λ is the wavelength of the incident laser beam. Since these dielectric material layer materials will be deposited using real processes, there will be some nanometers of variability, which may only serve to reduce the reflectance from the ideal case without variability. For purposes of description, low-refractive index dielectric materials can have a refractive index of <1.5 or <1.6 depending upon the semiconductor material, while high-refractive index dielectric materials can have a refractive index of >1.5 or >1.6. In the embodiment depicted in FIG. 2A there are four alternating high-refractive index dielectric material and low-refractive index dielectric material layers 130, 140, respectively, however other embodiments contemplate greater or fewer alternating high-refractive index dielectric material and low-refractive index dielectric material layers. Further, in the non-limiting embodiment shown in FIG. 2A, the top metal layer pads or metal bonding structures 128 are provided within the stack of alternating dielectric material layers forming the top laser damage mitigation structure 150 and have top surfaces coplanar with a top surface of a low refractive index dielectric material layer 140. As shown in a non-limiting embodiment depicted in FIG. 2A, incident IR laser beams 135 reflect off of the alternating high-refractive index dielectric material and low-refractive index dielectric material layers of laser damage mitigation structure 150 and further reflect off of the coplanar top surface of the top metal layer pads or metal bonding structures 128. In another example, FIG. 2B depicts a configuration of the laser damage mitigation structure having a sidewall edge abutting and touching different side edge portion of a BEOL metal bonding layer structure (upper, middle, or bottom, etc) 128 and/or of a BEOL via contact structure 125. FIG. 2C depicts a configuration of the laser damage mitigation structure having a sidewall edge abutting and touching the via contact or portion of a via contact 125 below a metal bonding structure 128.

FIG. 3 depicts a close-up view of a portion 151 of the laser damage mitigation structure 150 shown in FIG. 2A. In FIG. 3, there is shown in greater detail the laser beam reflections 136 reflecting from incident laser beam 135 at each of the interfaces 160 between adjacent alternating high-refractive index dielectric material and low-refractive index dielectric material layers 130, 140 of laser damage mitigation structure 150 and further reflecting at an interface between the bottom low-refractive index material layer 130 and the top surface of IDL material layer 110.

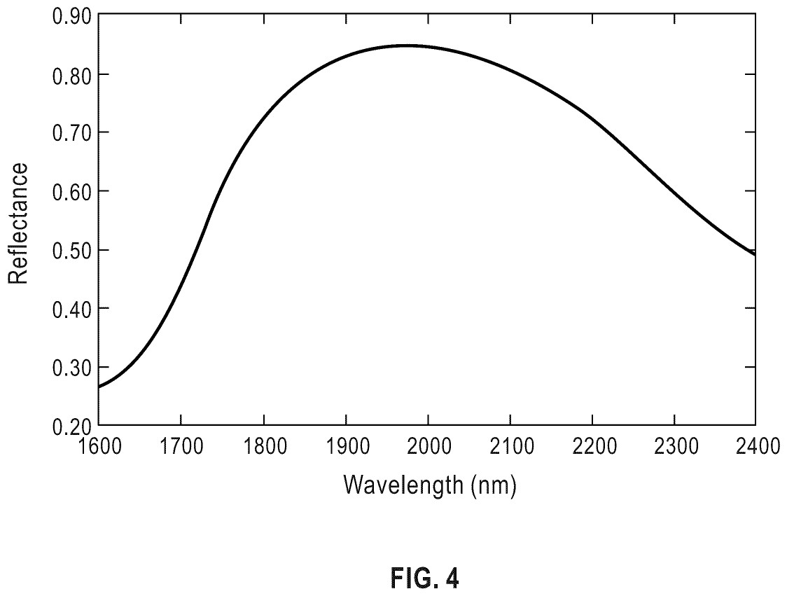

FIG. 4 depicts a plot 200 illustrating a degree of reflectance (ordinate axis) of the laser damage mitigation structure 150 as a function of incident light wavelength (abscissa) according to an embodiment. As shown, the laser damage mitigation structure 150 including the alternating layers alternating high-refractive index dielectric material and low-refractive index dielectric material layers 130, 140 provides a range of light reflectivity. For an exemplary configuration of a laser damage mitigation structure having three pairs of alternating SiN (refractive index (RI) equal to 2.2, at thickness=240 nm) and SiO₂ layer (RI=1.5, at a thickness=350 nm) where R=84% @2 μm wavelength, the peak reflectance is shown at incident light wavelengths of between 1900 nm-2100 nm.

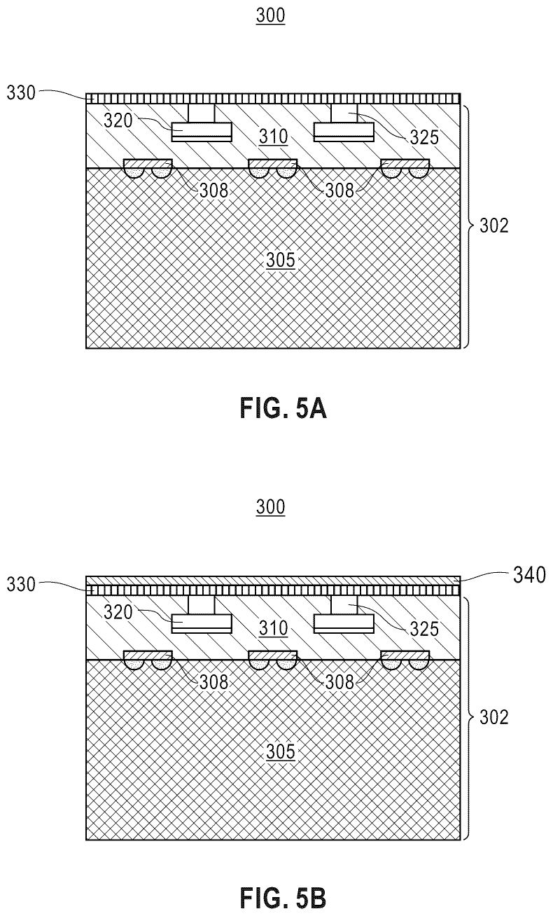

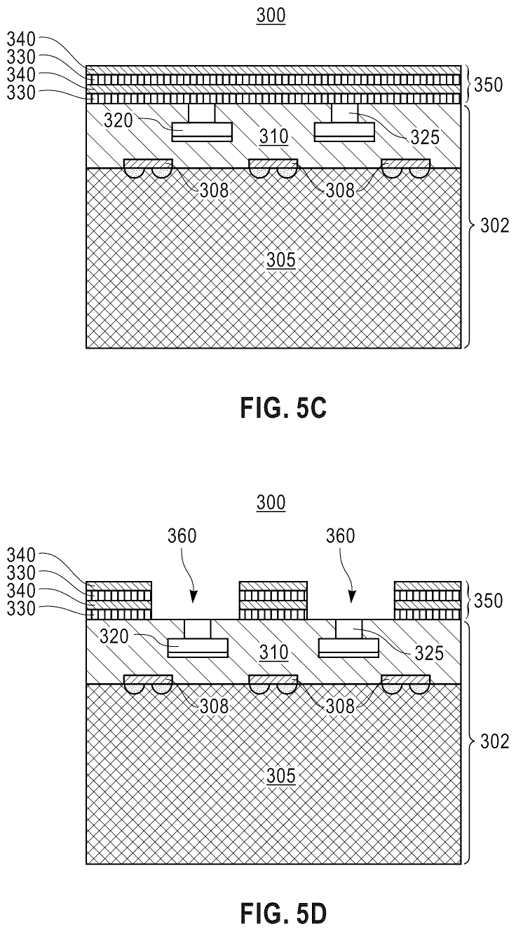

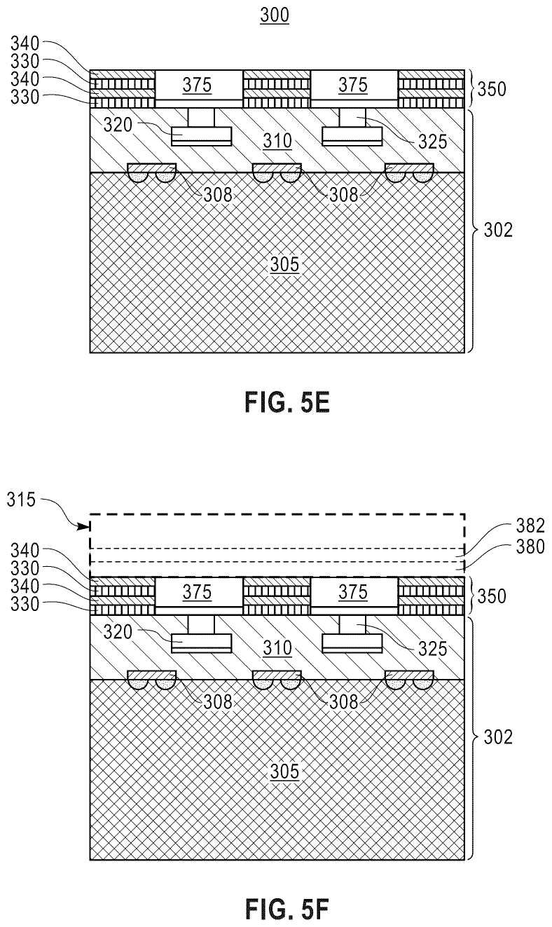

FIGS. 5A-5F depict a process flow 300 for fabricating the laser damage mitigation structure atop a semiconductor wafer. As shown in FIG. 5A, there is shown an initial intermediate semiconductor structure, a device wafer or wafer die 302 including a thinned substrate 302 on top of which are formed front-end-of-line (FEOL) devices 308, e.g., device components such as transistors, capacitors, resisters forming semiconductor circuits and systems and fabricated using known semiconductor manufacturing techniques. Upon thinned layer 305 is an interlevel dielectric (ILD) material layer 310 that further include conductive, e.g., metal connector/interconnect structures 320, e.g., including, but not limited to contacts, metallization wiring, via contacts 325, top metal layer pads or metal bonding structures, etc. for chip to package connections, etc. formed in the ILD layer 310 as part of middle-of-line (MOL) and/or BEOL semiconductor manufacturing techniques. ILD material layer 310 can be composed of an oxide, nitride or oxynitride material. In embodiments, interlevel dielectric material can be a low-k dielectric material such as an oxide dielectric material or a silicon doped oxide (e.g., SiCOH, SiCN SiCNH) and can include porous silicates, carbon doped oxides, silicon dioxides, silicon oxynitrides, carbon-doped silicon oxide (SiCOH) and porous variants thereof, silsesquioxanes, siloxanes, or other dielectric materials having, for example, a dielectric constant in the range of about 2 to about 4. As upper BEOL layers can be different than lower layers, upper BEOL ILD layer can be a SiCOH, e.g., like TEOS or FTEOS. Such a dielectric film can be deposited using a deposition process, e.g., chemical vapor deposition (CVD), plasma enhanced chemical vapor deposition (PECVD), physical vapor deposition (PVD) etc. Further, in an embodiment, the metal connector/interconnect structures 320, e.g., contacts, metallization wiring, vias, top metal layer pads or metal bonding structures, etc. can be formed using MOL single damascene or dual damascene processes.

In FIG. 5A, at top of ILD layer is deposited a low-refractive index dielectric material layer 330 by deposition processes such as CVD, PECVD, PVD or atomic layer deposition (ALD). Thicknesses of low refractive index dielectric material layer are dependent upon the laser wavelength being used. Using a low refractive index material such as SiCOH, the thickness can range from between 100 nm to 500 nm. In an example, non-limiting embodiment, the first low-refractive index dielectric material layer 330 deposited over ILD layer 310 is SiO₂ with a target thickness of about 350 nm.

Then, as shown in FIG. 5B, there is then deposited a high refractive index dielectric material layer 340 on top the low-refractive index dielectric material layer 330. Thicknesses of high-refractive index dielectric material layer 340 can vary depending upon the material and the laser wavelength being used. In an embodiment, the deposited high-refractive index dielectric material layer 340 is SiN with a target thickness of about 240 nm having a refractive index RI=2.2. Other high-RI, high-k materials can include, but are not limited to TiO2, HfO2, Al2O3, ZrO2, etc.

As shown in FIG. 5C, there is optionally shown the result of performing further deposition steps of alternating high-refractive index dielectric material and low-refractive index dielectric material layers 330, 340 by repeating the above dielectric material deposition steps of FIGS. 5A, 5B to get multiple pairs of alternating low-refractive index and high-refractive index dielectric layers 330, 340 in a multi-layer stack structure 350.

Continuing to FIG. 5D, there is performed further method steps of lithographic photoresist patterning on the top surface of multi-layer stack structure 350, and including photoresist mask deposition, exposure and development, and then conducting one or multiple etches to form trenches 360 through the multiple pairs of alternating low-refractive index and high-refractive index dielectric layers 330, 340 of the multi-layer stack structure 350. As shown in FIG. 5D, the etched openings or trenches 360 are located in alignment with respective underlying metal interconnect structures such as the underlying via contacts 325. An etch or multiple etches can be conducted using a dry etch process, a chemical wet etch process, or any combination thereof. When a dry etch is used, the dry etch can be a reactive ion etch (RIE) process, a plasma etch process, ion beam etching or laser ablation. The patterned photoresist material can be removed anytime after transferring the trench pattern into the laser damage mitigation stacked structure 350 utilizing a conventional stripping process.

After transferring the resist mask pattern into the underlying laser damage mitigation multi-layer stack structure 350 via a single etch or multiple etches to provide a resulting pattern of trenches 360 corresponding to a desired contact structure as illustrated in FIG. 5D, a metal material that can be used in the damascene process such as Cu, Ru, W, Co, Ta, TaN, Ti, TiN is then deposited to fill each trench 360.

FIG. 5D shows a resulting semiconductor structure formed after such damascene metal, e.g., Cu, material deposition steps to fill trenches with metal material 375. That is, using a single damascene or dual damascene processes using photolithographic damascene, etching and deposition processes known in the art, there is formed several metal contact structures 375 formed within the laser damage mitigation stacked structure 350 each having a surface that is coplanar with the top alternating layer 340 of the laser damage mitigation stacked structure 350. The damascene process for forming the metal material trench structures may include forming damascene metal material seed layer and then damascene metal material deposition steps (e.g., CVD, PVD+reflow processes to fill the trench(es).

FIG. 5F depicts the structure of FIG. 5E after performing subsequent processing steps that include attaching, e.g., adhering using adhesives or bonding with a bonding material, a mechanical handler wafer (or carrier wafer) 315 on top of the laser damage mitigation layer 350 to enhance the mechanical integrity of the underlying device wafer 300 for subsequent processing steps. Using known processes there can be deposited first an adhesive layer 380 on top of the laser mitigation stacked structure 350 of the device wafer to provide high adhesion and a release layer 382 located between the adhesive layer and a carrier wafer 315

The laser damage mitigation structure 350 for a semiconductor device wafer such as shown in FIGS. 2-3 that includes a multilayer-stack of alternate high-and low-index dielectric material layers adjacent to a top BEOL layer serves as a reflector for incoming laser beams that are used to de-bond a device wafer from a handle (or carrier) wafer, e.g., for chiplet technology. Benefits of using an Si Carrier include: increased tool compatibility, less contamination, thermal CTE match and high heat dissipation, as well as simplifying a supply chain. The damage mitigation structure and method is designed to prevent damage that can result from IR laser debonding techniques.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a stack of alternating layers of dielectric material, the alternating dielectric material layers comprising successive pairs of a high-refractive index dielectric material layer and a low-refractive index dielectric material layer and the stack having a side edge abutting a side edge of a back-end-of-line metal layer structure; and the stack of alternating layers configured to reflect an incident laser beam.

2. The semiconductor structure of claim 1, wherein a thickness t_{H} of the high-refractive index dielectric material layer is t_{H}=nλ/(4n_{H}) where n_{H} is an index of refraction of the high-index dielectric material and λ is the wavelength of the incident laser beam.

3. The semiconductor structure of claim 1, wherein a thickness t_{L} of the low-refractive index dielectric material layer is t_{L}=nλ/(4n_{L}) where n_{L} is an index of refraction of the low-index dielectric material and λ is the wavelength of the incident laser beam.

4. The semiconductor structure of claim 1, wherein the back-end-of-line metal layer structure comprises a metal bonding structure, the metal bonding structure formed in alignment within the stack.

5. The semiconductor structure of claim 1, wherein the back-end-of-line metal layer structure comprises a metal via contact structure contacting a metal bonding structure.

6. The semiconductor structure of claim 5, wherein a refractive index of the high-refractive index dielectric material layer comprises is greater than 1.6.

7. The semiconductor structure of claim 1, further comprising:
a handle wafer bonded to a top surface of the stack.

8. The semiconductor structure of claim 7, wherein the handle wafer is bonded to a top surface of the stack using one or more of: a bonding material of conductive material forming a laser release layer, a polymeric adhesive material layer, or both a laser release layer and adhesive layer.

9. The semiconductor structure of claim 1, further comprising:
one or more metal contact structures formed within the stack of alternating layers of dielectric material, the formed one or more metal contact structures connecting to one or more metal structures formed within said semiconductor wafer underlying said stack of alternating layers of dielectric material.

10. The semiconductor structure of claim 1, where the stack side edge abuts side edges of more than one back-end-of-line metal layer structure at different metallization layers.

11. A semiconductor structure comprising:
a stack of alternating layers of dielectric material, the alternating dielectric material layers comprising successive pairs of a high-refractive index dielectric material layer and a low-refractive index dielectric material layer and the stack having a side edge abutting side edges of at least one back-end-of-line metal layer structure; and the stack of alternating layers configured to reflect an incident laser beam.

12. The semiconductor structure of claim 11, wherein a thickness t_{H} of the high-refractive index dielectric material layer is t_{H}=nλ/(4n_{H}) where n_{H} is an index of refraction of the high-index dielectric material and λ is the wavelength of the incident laser beam; and
a thickness t_{L} of the low-refractive index dielectric material layer is t_{L}=nλ/(4n_{L}) where n_{L} is an index of refraction of the low-index dielectric material and λ is the wavelength of the incident laser beam.

13. The semiconductor structure of claim 12, wherein the at least one back-end-of-line metal layer structure comprises a metal bonding structure, the metal bonding structure formed in alignment within the stack.

14. The semiconductor structure of claim 13, wherein the at least one back-end-of-line metal layer structure comprises a metal via contact structure contacting the metal bonding structure,, the metal bonding structure formed in alignment within the stack.

15. The semiconductor structure of claim 14, wherein the metal bonding structure formed within the stack has a top surface co-planar with a top surface of said stack.

16. The semiconductor structure of claim 13, wherein the at least one back-end-of-line metal layer structures comprise a metal via contact structure contacting the metal bonding structure, the metal via contact structure further connecting to one or more metal structures formed within said semiconductor wafer underlying said stack of alternating layers of dielectric material, wherein the stack having a side edge abutting both side edges of said metal bonding structure and said metal via contact structure of said at least one back-end-of-line metal layer structure.

17. The semiconductor structure of claim 15, further comprising additional successive pairs of a high-refractive index dielectric material layer and low-refractive index dielectric material layer formed on top said coplanar surface.

18. A method of forming laser damage mitigation structure on a semiconductor wafer, the method comprising:
depositing a low-refractive index dielectric material layer of a target thickness on a top surface of the semiconductor die, having devices formed therein;
depositing a high-refractive index dielectric material layer of a target thickness on top the deposited low-refractive index dielectric material layer, the deposited low-refractive index dielectric material layer and high-refractive index dielectric material layer defining an initial pair of layers;
repeating the depositing of alternating layers of low-refractive index dielectric material layer and high-refractive index dielectric material layer on the initial pair to form a stacked structure of alternating low-refractive index and high-refractive index layers on top of the device wafer.

19. The method as claimed in claim 18, further comprising:
etching one or more openings in the stacked structure of alternating low-refractive index and high-refractive index layers;
filling the etched one or more opening with a metal material.

20. The method as claimed in claim 19, wherein the device wafer comprises a top metallization level of conductive interconnect structures, the etched one or more openings in said stacked structure of alternating low-refractive index and high-refractive index layers being aligned with respective top metallization level of conductive interconnect structures.
